(19) United States
(12) Patent Application Publication
(10) Pub. No.: US 2011/0115034 A1
(43) Pub. Date: May 19, 2011

(54) TRANSISTOR

(75) Inventors: Po-Yuan Lo, Taipei City (TW); Yu-Rung Peng, Taoyuan County (TW); Tarng-Shiang Hu, Hsinchu City (TW); Yi-Jen Chan, Taoyuan County (TW)

(73) Assignee: Industrial Technology Research Institute, Hsinchu (TW)

(21) Appl. No.: 12/732,187

(22) Filed: Mar. 26, 2010

(30) Foreign Application Priority Data
Nov. 19, 2009 (TW) 98139338

(51) Int. Cl. H01L 29/792

(52) U.S. Cl. 257/410; 257/E29.309

(57) ABSTRACT

A transistor including a substrate, a gate, a semiconductor layer, a stacked insulating layer and a source and a drain is provided. The gate is disposed on the substrate. The semiconductor layer is disposed on the substrate, and a first type carrier is the main carrier in the semiconductor layer. The stacked insulating layer is disposed between the semiconductor layer and the gate, and includes a first insulating layer and a second insulating layer. The first insulating layer contains a first group withdrawing the first type carrier, the second insulating layer contains a second group withdrawing a second type carrier, and the first insulating layer is disposed between the semiconductor layer and the second insulating layer. The source and the drain are disposed on the substrate and at two sides of the semiconductor layer.

### CROSS-REFERENCE TO RELATED APPLICATION

This application claims the priority benefit of Taiwan application serial no. 98139338, filed on Nov. 19, 2009. The entirety of the above-mentioned patent application is hereby incorporated by reference herein and made a part of specification.

### BACKGROUND OF THE INVENTION

1. Field of the Invention

The invention relates to a semiconductor device, and more particularly, to a transistor.

2. Description of Related Art

The transistor plays a role of driving the display medium in the display, and in the process of driving the display medium, the stability of the electrical property of the transistor affects the image contrast displayed by the display medium. Thus, for the display to have superior display quality, the transistor array has to maintain stable threshold voltage and operating current.

Generally, the transistor has stable threshold voltage and operating current in an environment that is dark and lacks moisture and oxygen. However, the transistor is highly photosensitive; that is, when the light irradiates the transistor, the electrical property of the transistor is affected immediately, so as to result in electrical drift phenomenon such as threshold voltage shift, sub-threshold swing increase, operating current change, and so on. In addition, the above changes in electrical property cannot be recovered in milliseconds. The display image and the display quality of the display are greatly affected accordingly.

Hence, this field demands a transistor having high electrical stability so as to maintain superior electrical property in the operation process.

### SUMMARY OF THE INVENTION

The invention is directed to a transistor having high electrical stability and low photosensitivity.

The invention is directed to a transistor including a substrate, a gate, a semiconductor layer, a stacked insulating layer, and a source and a drain. The gate is disposed on the substrate. The semiconductor layer is disposed on the substrate and adopts a first type carrier as the main carrier. The stacked insulating layer is disposed between the semiconductor layer and the gate, and includes at least a first insulating layer and a second insulating layer. Herein, the first insulating layer contains a first group withdrawing the first type carrier, the second insulating layer contains a second group withdrawing a second type carrier, and the first insulating layer is disposed between the semiconductor layer and the second insulating layer. The source and the drain are disposed on the substrate and at two sides of the semiconductor layer.

In light of the foregoing, the transistor of the invention includes the stacked insulating layer, which is stacked by insulating layers having restraining forces toward different carriers. As a consequence, the electrical stability of the transistor is enhanced and the photosensitivity of the transistor is reduced, such that the transistor has superior electrical property.

In order to make the aforementioned and other features of the present invention more comprehensible, several embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic cross-sectional view of a transistor according to a first embodiment of the invention.

FIG. 2 is a schematic cross-sectional view of a transistor according to a second embodiment of the invention.

FIG. 3 is a schematic cross-sectional view of a transistor according to a third embodiment of the invention.

FIG. 4 is a schematic cross-sectional view of a transistor according to a fourth embodiment of the invention.

FIG. 5 is a schematic cross-sectional view of a transistor according to a fifth embodiment of the invention.

FIG. 6A and FIG. 6B are a threshold voltage and an operating current of a top gate transistor with single insulating layer and a transistor with stacked insulating layers operated in the dark, respectively.

FIG. 6C and FIG. 6D are a threshold voltage and an operating current of a top gate transistor with single insulating layer and a transistor with stacked insulating layers operated during light irradiation, respectively.

### DESCRIPTION OF EMBODIMENTS

### First Embodiment

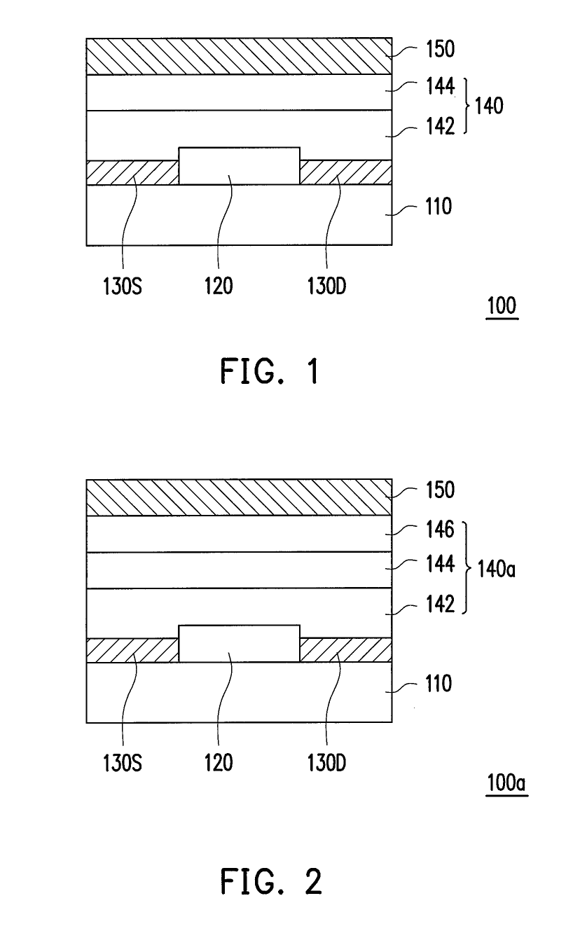

FIG. 1 is a schematic cross-sectional view of a transistor according to a first embodiment of the invention.

Referring to FIG. 1, a transistor 100 includes a substrate 110, a semiconductor layer 120, a source 130S and a drain 130D, a stacked insulating layer 140, and a gate 150. The semiconductor layer 120 is disposed on the substrate 110 and adopts a first type carrier as the main carrier. The source 130S and the drain 130D are disposed on the substrate 110 and at two sides of the semiconductor layer 120. Specifically, in the present embodiment, the first type carrier is a hole; that is, the semiconductor layer 120 is a P-type semiconductor layer having more holes, for example. The semiconductor layer 120 is made of inorganic semiconductor or organic semiconductor. Here, inorganic semiconductor includes amorphous silicon, polysilicon, or oxide semiconductors, and organic semiconductor includes organic small molecules, organic polymers, or a mixture thereof. Moreover, the substrate 110 is a rigid substrate or a flexible substrate. The rigid substrate is made of, for instance, glass, quartz, or silicon wafer. The flexible substrate is made of, for example, plastic (i.e. acrylic material), metal foil or paper. The source 1305 and the drain 130D are made of gold, silver, aluminum, copper, chromium, titanium, or an alloy thereof, for example. Additionally, the source 130S and the drain 130D are formed by performing, for instance, a physical vapor deposition (PVD) process.

The gate 150 is disposed on the substrate 110. The stacked insulating layer 140 is disposed between the semiconductor layer 120 and the gate 150, and includes a first insulating layer 142 and a second insulating layer 144. Herein, the first insulating layer 142 contains a first group withdrawing the first type carrier, the second insulating layer 144 contains a second group withdrawing a second type carrier, and the first insulating layer 142 is disposed between the semiconductor layer 120 and the second insulating layer 144. In the present embodiment, the first type carrier is a hole and the second type carrier is an electron. That is, the semiconductor layer 120 adopts holes as the main carrier, the first insulating layer 142 contains the first group which withdraws holes, and the second insulating layer 144 contains the second group which withdraws electrons. In detail, the first group, for example, is a group capable of withdrawing holes, and includes an alkyl group, an alcohol group, an amino group, and other groups having the ability to release electrons. The second group, for example, is a group capable of withdrawing electrons, and includes a halogen group, a nitrile group, a carbonyl group, a nitro group, and other groups having the ability to gain electrons.

In the present embodiment, the first insulating layer 142 and the second insulating layer 144 are made of inorganic insulating material or organic insulating material, such as low dielectric constant material having a dielectric constant smaller than 4, for example. Further, the first insulating layer 142 and the second insulating layer 144 are formed by performing, for example, a spin coating process. The total thickness of the stacked insulating layer 140 ranges from 220 nm-800 nm, and preferably ranges from 230 nm-300 nm. The first insulating layer 142 is made of, for instance, poly(vinyl pyrrolidone) (PVP), poly(vinyl phenol) (PVP), polyphenylene sulfide (PPS), phenol resin, or other insulating materials containing groups that have the ability to release electrons. The second insulating layer 144 is made of, for example, polyethylene tetrafluoride, polyarylate, or other insulating materials containing groups that have the ability to gain electrons. In addition, the second insulating layer 144 having the ability to withdraw electrons, for example, includes metal particles such as gold, silver, or platinum. The metal particles occupy less than 0.1 wt % in the second insulating layer 144. For example, the second insulating layer 144 includes a bistabled organic memory material formed by [4-cyano-2,4,4-trimethyl-2-methylsulfonylthiocarbonylsulfonyl-poly (butyric acid 1-adamantan-1-yl-1-methyl-ethyl ester)] (PCm) with polymer-chain-stabilized gold nanoparticles (PCm-Au NPs).

It should be noted that the stacked insulating layer 140 further includes a third insulating layer (not shown). The third insulating layer is disposed between the gate 150 and the second insulating layer 144. The third insulating layer includes an insulating material containing a group which withdraws holes, an insulating material containing a group which withdraws electrons, or general insulating materials. Further, the gate 150 is formed by, for example, first forming a gate material layer, and patterning the gate material layer using lithography and etching processes. The gate material layer is made of metal, doped polysilicon, transparent conductive oxide, or so on. The gate material layer is formed by performing a PVD process or a chemical vapor deposition (CVD) process, for instance.

In the present embodiment, the first insulating layer 142 having the ability to trap holes (donor-like trap) and the second insulating layer 144 having the ability to trap electrons (acceptor-like trap) are sequentially stacked on the semiconductor layer 120 having more holes. Accordingly, after being stacked, the first insulating layer 142 and the second insulating layer 144 that might compensate the donor-like trap and acceptor-like trap each other. This small amount of acceptor-like trap is capable of restraining electron carriers in the semiconductor layer 120. The electron carriers inhibit the accumulation of holes at the interface between the semiconductor layer and the insulating layer. Therefore, when the light irradiates the semiconductor layer of the transistor, since most of the hole carriers in the semiconductor layer recombine with electrons generated during the irradiation, the electrical stability of the transistor 100 is maintained and the photosensitivity of the transistor 100 is reduced, such that the transistor 100 has superior electrical property.

Consequently, when the transistor is applied in the display (i.e. flexible electronic display apparatuses including electronic paper, flexible display, and so on) as a driving transistor, the transistor still maintains electrical properties such as stable threshold voltage and operating current even though the light irradiates a surface of the transistor through a display medium, so that the display has superior display quality. It should be noted that comparing to a conventional method where a metal mask is utilized to block the light from entering the transistor, the transistor of the invention is capable of reducing the electrical drift level caused by irradiation without adopting an additional material layer. Thus, the fabrication process of the transistor of the invention is compatible with the conventional fabrication process, and no additional fabrication cost is required. Furthermore, since the number of traps in organic insulating layers are greater than those in inorganic insulating layers, a conventional organic transistor usually has unstable electrical property. As a consequence, the stacked insulating layer of the invention is adopted in the organic transistor to enhance the electrical stability of the organic transistor.

### Second Embodiment

FIG. 2 is a schematic cross-sectional view of a transistor according to a second embodiment of the invention. A transistor 100a of the present embodiment and the transistor 100 of FIG. 1 have similar structures; however, the main difference is that the transistor 100a further includes a third insulating layer 146. Thus, only the different parts are described hereinafter.

Referring to FIG. 2, the transistor 100a includes the substrate 110, the semiconductor layer 120, the source 130S and the drain 130D, a stacked insulating layer 140a, and the gate 150. The stacked insulating layer 140a includes the first insulating layer 142, the second insulating layer 144, and the third insulating layer 146 stacked sequentially on the semiconductor layer 120. In the present embodiment, the semiconductor layer 120 adopts holes as the main carrier, and is, for example, a P-type semiconductor layer. The first insulating layer 142, for example, contains the first group which withdraws holes, the second insulating layer 144, for example, contains the second group which withdraws electrons, and the third insulating layer 146 contains a third group which withdraws holes, for instance. Here, the third group includes an alkyl group, an alcohol group, an amino group, and other groups having the ability of releasing electrons.

In the present embodiment, the first insulating layer 142, the second insulating layer 144, and the third insulating layer 146 are made of inorganic insulating material or organic insulating material, such as low dielectric constant material having a dielectric constant smaller than 4, for example. In addition, the first insulating layer 142, the second insulating layer 144, and the third insulating layer 146 are formed by performing, for example, a spin coating process. The total thickness of the stacked insulating layer 140a ranges from 220 nm˜800 nm, and preferably ranges from 230 nm˜300 nm. The first insulating layer 142 and the second insulating layer 144 are made of materials described in the first embodiment, and the third insulating layer 146 is made of, for instance, poly(vinyl pyrrolidone), poly(vinyl phenol), PPS, phenol resin, or other insulating materials containing groups that have the ability to release electrons. It should be noted that the stacked insulating layer 140a may further include a fourth insulating layer (not shown). The fourth insulating layer is disposed between the gate 150 and the third insulating layer 146. The fourth insulating layer includes an insulating material containing a group which withdraws holes, an insulating material containing a group which withdraws electrons, or general insulating materials. In other words, although the present embodiment adopts the stacked insulating layer 140a, stacked by three layers of insulating layers 142, 144, 146, as an example, the invention is not limited thereto, and a user can form various stacked insulating layers according to the stacking methods illustrated in the invention.

As aforementioned, in the present embodiment, the first insulating layer 142 having the ability to withdraw holes, the second insulating layer 144 having the ability to withdraw electrons, and the third insulating layer 146 having the ability to withdraw holes are sequentially stacked on the semiconductor layer 120 having more holes. That is, according to the type of the main carrier in the semiconductor layer, the insulating layers having the ability to withdraw holes and the insulating layers having the ability to withdraw electrons are sequentially stacked on the semiconductor layer in an interlacing manner. Accordingly, after being stacked, the insulating layers that have restraining forces toward different carriers are capable of offsetting the number of valid trap and generating small amount of acceptor-like trap. This small amount of acceptor-like trap is capable of restraining electron carriers in the semiconductor layer. The electron carriers inhibit the accumulation of holes at the interface between the semiconductor layer and the insulating layer.

Therefore, when the light irradiates the semiconductor layer of the transistor, since most of the hole carriers in the semiconductor layer recombine with electrons generated during the irradiation, the electrical stability of the transistor is maintained and the photosensitivity of the transistor is reduced, such that the transistor has superior electrical property. Consequently, when the transistor is applied in the display (i.e. flexible electronic display apparatuses including electronic paper, flexible display, and so on) as a driving transistor, the transistor still maintains electrical properties such as stable threshold voltage and operating current even though the light irradiates a surface of the transistor, so that the display has superior quality.

### Third Embodiment

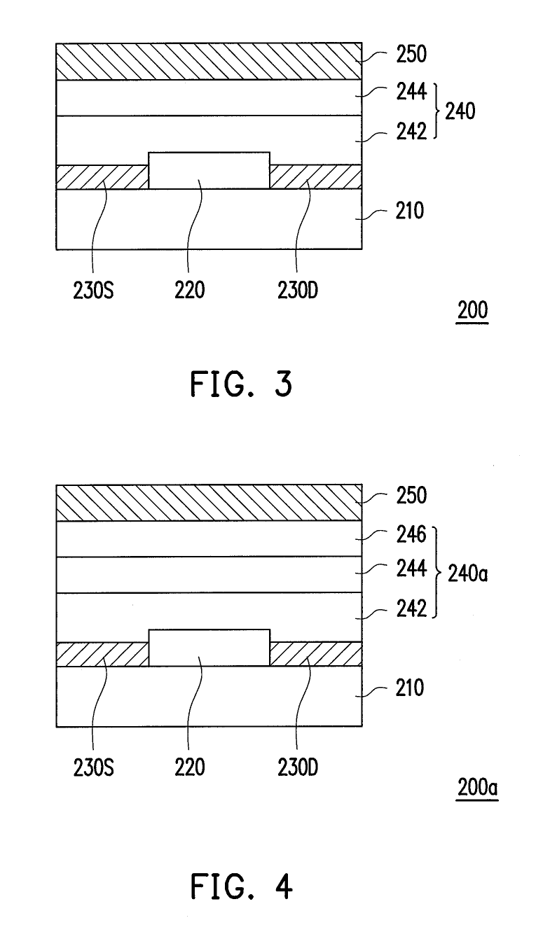

FIG. 3 is a schematic cross-sectional view of a transistor according to a third embodiment of the invention. A transistor 200 of the present embodiment and the transistor 100 of FIG. 1 have similar structures; however, the main difference is that the semiconductor layer 220 of the transistor 200 adopts electrons as the main carrier. Thus, only the different parts are described hereinafter.

Referring to FIG. 3, a transistor 200 includes a substrate 210, a semiconductor layer 220, a source 230S and a drain 230D, a stacked insulating layer 240, and a gate 250. The semiconductor layer 220 is disposed on the substrate 210 and adopts electrons as the main carrier. The gate 250 is disposed on the substrate 210. The stacked insulating layer 240 is disposed between the semiconductor layer 220 and the gate 250, and includes a first insulating layer 242 and a second insulating layer 244. Herein, the first insulating layer 242 contains a group which withdraws electrons, the second insulating layer 244 contains a group that withdraws holes, and the first insulating layer 242 is disposed between the semiconductor layer 220 and the second insulating layer 244. The source 230S and the drain 230D are disposed on the substrate 210 and at two sides of the semiconductor layer 220. The substrate 210, the gate 250, and the source 230S and the drain 230D are made of and formed by materials and methods that are well-known to those skilled in the art or described in the first embodiment, and detailed description is thereof omitted.

In the present embodiment, the semiconductor layer 220 is an N-type semiconductor layer having more electrons. The semiconductor layer 220 is made of inorganic semiconductor or organic semiconductor. Here, inorganic semiconductor includes amorphous silicon, polysilicon, or oxide semiconductors, and organic semiconductor includes organic small molecules, organic polymers, or a mixture thereof. The first insulating layer 242 contains a group that withdraws electrons, and this group includes a halogen group, a nitrile group, a carbonyl group, a nitro group, and other groups having the ability to gain electrons. The second insulating layer 244 contains a group that withdraws holes, and this group includes an alkyl group, an alcohol group, an amino group, and other groups having the ability to release electrons.

In addition, the first insulating layer 242 and the second insulating layer 244 are made of inorganic insulating material or organic insulating material, such as low dielectric constant material having a dielectric constant smaller than 4, for example. Further, the first insulating layer 242 and the second insulating layer 244 are formed by performing, for example, a spin coating process. The total thickness of the stacked insulating layer 240 ranges from 220 nm˜800 nm, and preferably ranges from 230 nm-300 nm. The first insulating layer 242 is made of, for example, polyethylene tetrafluoride, polyarylate, or other insulating materials containing groups that have the ability to gain electrons. The second insulating layer 244 is made of, for instance, poly(vinyl pyrrolidone), poly(vinyl phenol), PPS, phenol resin, or other insulating materials containing groups that have the ability to release electrons. Besides, the first insulating layer 242 having the ability to withdraw electrons, for example, includes metal particles such as gold, silver, or platinum. The metal particles occupy less than 0.1 wt % in the first insulating layer 242. For example, the first insulating layer 242 includes a bistabled organic memory material formed by [4-cyano-2,4,4-trimethyl-2-methylsulfonylthiocarbonylsulfonyl-poly (butyric acid 1-adamantan-1-yl-1-methyl-ethyl ester)] (PCm) with polymer-chain-stabilized gold nanoparticles (PCm-Au NPs). The stacked insulating layer 240 may further include a third insulating layer (not shown). The third insulating layer is disposed between the gate 250 and the second insulating layer 244. The third insulating layer includes an insulating material containing a group which withdraws electrons, an insulating material containing a group which withdraws holes, or general insulating materials.

In the present embodiment, the first insulating layer 242 having the ability to withdraw electrons and the second insulating layer 244 having the ability to withdraw holes are sequentially stacked on the semiconductor layer 220 having more electrons. Accordingly, after being stacked, the first insulating layer 242 and the second insulating layer 244 that have restraining forces toward different carriers are capable of offsetting the number of valid trap and generating small amount of donor-like trap. This small amount of donor-like trap is capable of restraining hole carriers in the semiconductor layer 220. The hole carriers inhibit the accumulation of electrons at the interface between the semiconductor layer and the insulating layer.

Therefore, when the light irradiates the semiconductor layer of the transistor, since most of the electron carriers in the semiconductor layer recombine with holes generated during the irradiation, the electrical stability of the transistor is maintained and the photosensitivity of the transistor is reduced, such that the transistor has superior electrical property. Consequently, when the transistor is applied in the display (i.e. flexible electronic display apparatuses including electronic paper, flexible display, and so on) as a driving transistor, the transistor still maintains electrical properties such as stable threshold voltage and operating current even though the light irradiates the transistor, so that the display has superior quality.

### Fourth Embodiment

FIG. 4 is a schematic cross-sectional view of a transistor according to a fourth embodiment of the invention. A transistor 200a of the present embodiment and the transistor 200 of FIG. 3 have similar structures; however, the main difference is that the transistor 200a further includes a third insulating layer 246. Thus, only the different parts are described hereinafter.

Referring to FIG. 4, the transistor 200a includes the substrate 210, the semiconductor layer 220, the source 230S and the drain 230D, a stacked insulating layer 240a, and the gate 250. The stacked insulating layer 240a includes the first insulating layer 242, the second insulating layer 244, and the third insulating layer 246 stacked sequentially on the semiconductor layer 220. In the present embodiment, the semiconductor layer 220 adopts electrons as the main carrier, and is, for example, an N-type semiconductor layer. The first insulating layer 242, for example, contains the group which withdraws electrons, the second insulating layer 244, for example, contains the group which withdraws holes, and the third insulating layer 246 contains a group which withdraws electrons, for instance. Here, the group contained in the third insulating layer 246 includes a halogen group, a nitrile group, a carbonyl group, a nitro group, and other groups having the ability to gain electrons.

In the present embodiment, the first insulating layer 242, the second insulating layer 244, and the third insulating layer 246 are made of inorganic insulating material or organic insulating material, such as low dielectric constant material having a dielectric constant smaller than 4, for example. In addition, the first insulating layer 242, the second insulating layer 244, and the third insulating layer 246 are formed by performing, for example, a spin coating process. The total thickness of the stacked insulating layer 240a ranges from 220 nm˜800 nm, and preferably ranges from 230 nm˜300 nm. Here, the first insulating layer 242 and the second insulating layer 244 are made of materials described in the third embodiment. The third insulating layer 246 is made of polyethylene tetrafluoride, polyarylate, or other insulating materials containing groups that have the ability to gain electrons. Further, the third insulating layer 246 is formed by performing a spin coating process, for instance. It should be noted that the stacked insulating layer 240a may further include a fourth insulating layer (not shown). The fourth insulating layer is disposed between the gate 250 and the third insulating layer 246. The fourth insulating layer includes an insulating material containing a group which withdraws holes, an insulating material containing a group which withdraws electrons, or general insulating materials. In other words, although the present embodiment adopts the stacked insulating layer 240a, which is stacked by three layers of insulating layers 242, 244, 246, as an example, the invention is not limited thereto, and the user can form various stacked insulating layers according to the stacking methods illustrated in the invention.

As aforementioned, in the present embodiment, the first insulating layer 242 having the ability to withdraw electrons, the second insulating layer 244 having the ability to withdraw holes, and the third insulating layer 246 having the ability to withdraw electrons are sequentially stacked on the semiconductor layer 220 having more electrons. That is, the insulating layers having the ability to withdraw electrons and the insulating layers having the ability to withdraw holes are sequentially stacked on the semiconductor layer in an interlacing manner, where the semiconductor layer has more electrons. Accordingly, after being stacked, the insulating layers that have restraining forces toward different carriers are capable of offsetting the number of valid trap and generating small amount of donor-like trap. This small amount of donor-like trap is capable of restraining hole carriers from the semiconductor layer. The hole carriers inhibit the accumulation of electrons at the interface between the semiconductor layer and the insulating layer.

Therefore, when the light irradiates the semiconductor layer of the transistor, since most of the electron carriers in the semiconductor layer recombine with holes generated during the irradiation, the electrical stability of the transistor is maintained and the photosensitivity of the transistor is reduced, such that the transistor has superior electrical property. Consequently, when the transistor is applied in the display (i.e. flexible electronic display apparatuses including electronic paper, flexible display, and so on) as a driving transistor, the transistor still maintains electrical properties such as stable threshold voltage and operating current even though the light irradiates a surface of the transistor, so that the display has superior quality.

### Fifth Embodiment

The above embodiments adopt the transistors 100, 100a, 200, 200a each having a top gate structure as examples; however, the transistor of the invention can also adopt a bottom gate structure.

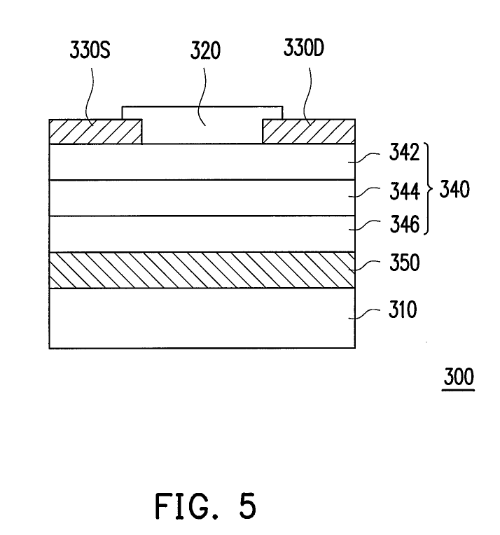

FIG. 5 is a schematic cross-sectional view of a transistor according to a fifth embodiment of the invention.

As shown in FIG. 5, components of a transistor 300 are similar to those of the transistor 100 in FIG. 2; however, the transistor 300 has a bottom gate structure. The transistor 300 includes a substrate 310, a semiconductor layer 320, a source 330S and a drain 330D, a stacked insulating layer 340, and a gate 350. The semiconductor layer 320 is disposed on the substrate 310 and located on the top of the gate 350, and adopts a first type carrier as the main carrier. The source 330S and the drain 330D are disposed at two sides of the semiconductor layer 320 and located on the top of the gate 350. The stacked insulating layer 340 is disposed between the semiconductor layer 320 and the gate 350, and includes a first insulating layer 342, a second insulating layer 344, and a third insulating layer 346. The first insulating layer 342 is adjoined to the semiconductor layer 320, the third insulating layer 346 is adjoined to the gate 350, and the second insulating layer 344 is disposed between the first insulating layer 342 and the third insulating layer 346. Herein, the first insulating layer 342 contains a first group withdrawing a first type carrier, the second insulating layer 344 contains a second group withdrawing a second type carrier, and the third insulating layer 346 contains a third group withdrawing a third type carrier.

In other words, when the semiconductor layer 320 adopts the first type carrier as the main carrier, the first insulating layer 342 that contains a group withdrawing the first type carrier is disposed to be adjoined to the semiconductor layer 320, and the second insulating layer 344 that contains a group withdrawing the second type carrier and the third insulating layer 346 that contains a group withdrawing the first type carrier are disposed in an interlacing manner. That is, as shown in FIG. 5, the first insulating layer 342, the second insulating layer 344, and the third insulating layer 346 are sequentially formed on the semiconductor layer 320 in a direction from the semiconductor layer 320 to the substrate 310. When the first type carrier in the semiconductor layer 320 is the hole rich, the semiconductor layer 320, the first insulating layer 342, the second insulating layer 344, and the third insulating layer 346 can refer to the semiconductor layer 120, the first insulating layer 142, the second insulating layer 144, and the third insulating layer 146 described in the second embodiment, and the details are thus not repeated. When the first type carrier in the semiconductor layer 320 is the electron rich, the semiconductor layer 320, the first insulating layer 342, the second insulating layer 344, and the third insulating layer 346 can refer to the semiconductor layer 220, the first insulating layer 242, the second insulating layer 244, and the third insulating layer 246 described in the fourth embodiment, and the details are thus not repeated hereinafter. Furthermore, although the stacked insulating layer 340 including three insulating layers 342, 344, 346 is used as an example in the present embodiment, the transistor having the bottom gate structure can also be a stacked insulating layer stacked by two insulating layers (i.e. the stacked insulating layer merely includes the first insulating layer 342 and the second insulating layer 344), or a stacked insulating layer stacked by other numbers of insulating layers according to the stacking method illustrated in the invention.

In the present embodiment, the stacked insulating layer is disposed in the transistor 300 having the bottom gate structure. After being stacked, the insulating layers that have restraining forces toward different carriers enhance electrical stability of the transistor 300 and reduce the photosensitivity of the transistor 300, such that the transistor has superior electrical property. Accordingly, whether operating in a dark or irradiated environment, the transistor having the bottom gate structure is capable of maintaining electrical properties such as stable threshold voltage and operating current.

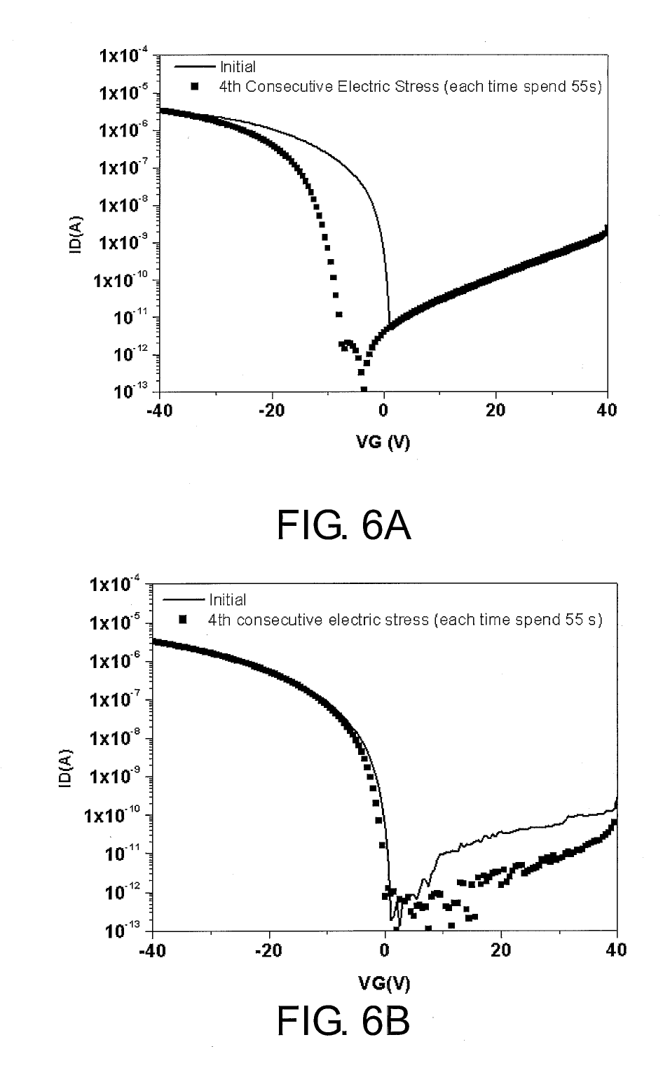

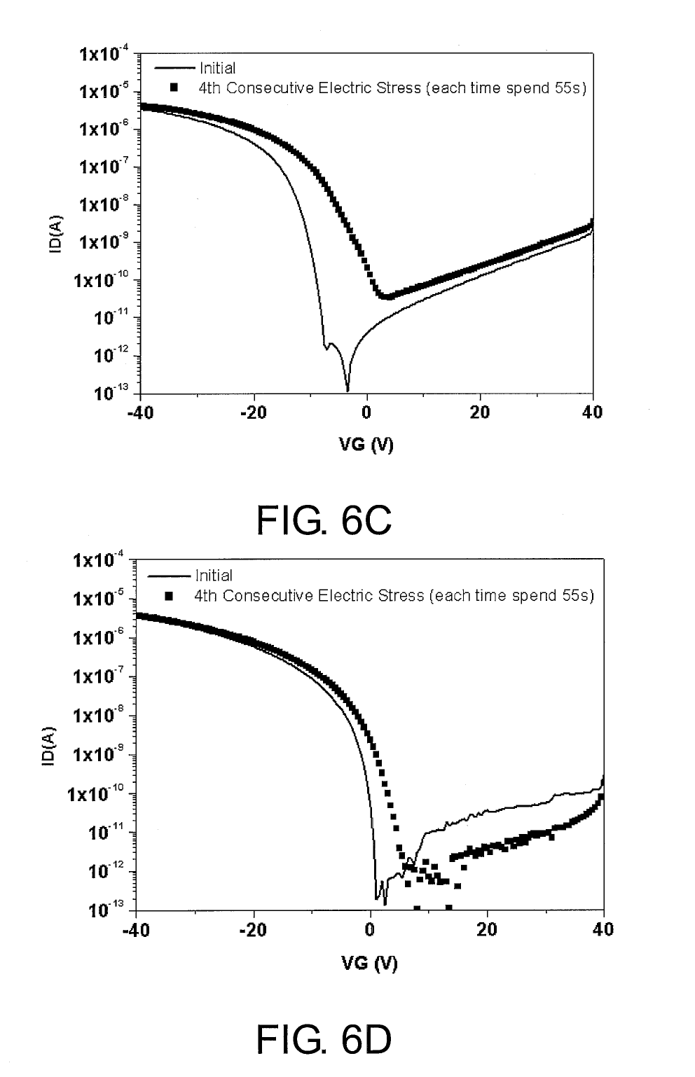

Herein, an experiment data is provided. In the experiment, a top gate transistor with single insulating layer (PVP(poly(vinyl phenol)), 230 nm) and the transistor with stacked insulating layers (PVP/PCm-Au NPs/PVP, 263 nm) are operated in the dark with four consecutive gate voltage sweep from V_{G}=40 V to −40 V and total stress time is 220 s. The threshold voltage and operating current of the transistors are measured, and the results are shown in FIG. 6A and FIG. 6B, respectively. As shown in FIG. 6A, the transistor with single insulating layer has a degradation of threshold voltage and operating current. In contrast, as shown in FIG. 6B, the transistor with stacked insulating layers has a relatively stable threshold voltage and operating current. The experiment results showed that the transistor with stacked insulating layers is capable of maintaining electrical properties such as stable threshold voltage and operating current.

Moreover, the transistors are operated with four consecutive gate voltage sweep from V_{G}=40 V to −40 V during light irradiation, and total stress time is 220 s. In this experiment, the photon intensity of light has been verified as 9 μW by using photodiode sensor of OPHIR PD 300-UV. The threshold voltage and operating current of the transistors are measured, and the results are shown in FIG. 6C and FIG. 6D, respectively. As shown in FIG. 6C, the transistor with single insulating layer (PVP) has a degradation of threshold voltage and operating current. In contrast, as shown in FIG. 6D, the transistor with stacked insulating layers (PVP/PCm-Au NPs) also showed a stable threshold voltage and operating current even operated in the dark. In detail, during light irradiation, the electron-hole pairs can generate in the semiconductor layer, which generally cause the photovoltaic effect to influence the threshold voltage shift. As shown in FIG. 6C, the photovoltaic effect in transistor with single insulating layer induced a threshold voltage shift from −7 V to 2 V. However, as shown in FIG. 6D, the transistor with stacked insulating layers has a stable threshold voltage within 3 V.

In summary, the transistor of the invention includes the stacked insulating layer, which is stacked by insulating layers having restraining forces toward different carriers. As a consequence, the electrical stability of the transistor is enhanced and the photosensitivity of the transistor is reduced, such that the transistor has superior electrical property. In other words, even when operating in an irradiating environment, the transistor of the invention is capable of maintaining electrical properties such as stable threshold voltage and operating current.

Therefore, when the transistor is adopted in the display, the transistor is capable of maintaining stable electrical property even if the light irradiates the surface of the transistor through the display medium, so that the transistor has superior display quality. In addition, comparing to a conventional method where a metal mask is utilized to block the light from entering the transistor, the transistor of the invention is capable of reducing the electrical drift level caused by irradiation without adopting an additional material layer. Thus, the fabrication process of the transistor of the invention is compatible with the conventional fabrication process, and no additional fabrication cost is required. Moreover, the transistor structure of the invention can be adopted in organic transistors to enhance electrical stability thereof.

Although the invention has been described with reference to the above embodiments, it will be apparent to one of the ordinary skill in the art that modifications to the described embodiment may be made without departing from the spirit of the invention. Accordingly, the scope of the invention will be defined by the attached claims not by the above detailed descriptions.

What is claimed is:

1. A transistor, comprising:
a substrate;
a gate, disposed on the substrate;
a semiconductor layer, disposed on the substrate and adopting a first type carrier as a main carrier;
a stacked insulating layer, disposed between the semiconductor layer and the gate, and comprising:
a first insulating layer, containing a first group withdrawing the first type carrier; and
a second insulating layer, containing a second group withdrawing a second type carrier, wherein the first insulating layer is disposed between the semiconductor layer and the second insulating layer; and
a source and a drain, disposed on the substrate and at two sides of the semiconductor layer.

2. The transistor as claimed in claim 1, wherein the first type carrier is a hole and the second type carrier is an electron.

3. The transistor as claimed in claim 2, wherein the semiconductor layer is a P-type semiconductor layer.

4. The transistor as claimed in claim 2, wherein the first group comprises an alkyl group, an alcohol group, and an amino group.

5. The transistor as claimed in claim 2, wherein the second group comprises a halogen group, a nitrile group, a carbonyl group, and a nitro group.

6. The transistor as claimed in claim 2, wherein the stacked insulating layer further comprises a third insulating layer containing a third group withdrawing the first type carrier, and the third insulating layer is disposed between the second insulating layer and the gate.

7. The transistor as claimed in claim 6, wherein the third group comprises an alkyl group, an alcohol group, and an amino group.

8. The transistor as claimed in claim 2, wherein the second insulating layer comprises metal particles.

9. The transistor as claimed in claim 8, wherein the metal particles occupy less than 0.1 wt % in the second insulating layer.

10. The transistor as claimed in claim 8, wherein the metal particles comprise gold, silver, or platinum.

11. The transistor as claimed in claim 1, wherein the first type carrier is an electron and the second type carrier is a hole.

12. The transistor as claimed in claim 11, wherein the semiconductor layer is an N-type semiconductor layer.

13. The transistor as claimed in claim 11, wherein the first group comprises a halogen group, a nitrile group, a carbonyl group, and a nitro group.

14. The transistor as claimed in claim 11, wherein the second group comprises an alkyl group, an alcohol group, and an amino group.

15. The transistor as claimed in claim 11, wherein the first insulating layer comprises metal particles.

16. The transistor as claimed in claim 15, wherein the metal particles occupy less than 0.1 wt % in the first insulating layer.

17. The transistor as claimed in claim 15, wherein the metal particles comprise gold, silver, or platinum.

18. The transistor as claimed in claim 11, wherein the stacked insulating layer further comprises a third insulating layer containing a third group withdrawing the first type carrier, and the third insulating layer is disposed between the second insulating layer and the gate.

19. The transistor as claimed in claim 18, wherein the third group comprises a halogen group, a nitrile group, a carbonyl group, and a nitro group.

20. The transistor as claimed in claim 18, wherein the third insulating layer comprises metal particles.

21. The transistor as claimed in claim 20, wherein the metal particles occupy less than 0.1 wt % in the third insulating layer.

22. The transistor as claimed in claim 20, wherein the metal particles comprise gold, silver, or platinum.

23. The transistor as claimed in claim 1, wherein a total thickness of the stacked insulating layer ranges from 220 nm˜800 nm.
